(19) United States
(12) Patent Application Publication
(10) Pub. No.: US 2016/0322377 A1
(43) Pub. Date: Nov. 3, 2016

(54) SEMICONDUCTOR MEMORY DEVICE

(71) Applicant: KABUSHIKI KAISHA TOSHIBA, Minato-ku (JP)

(72) Inventor: Kenichi IDE, Kuwana (JP)

(73) Assignee: KABUSHIKI KAISHA TOSHIBA, Minato-ku (JP)

(21) Appl. No.: 14/834,700

(22) Filed: Aug. 25, 2015

Related U.S. Application Data
(60) Provisional application No. 62/153,891, filed on Apr. 28, 2015.

(51) Int. Cl. H01L 27/115; H01L 21/768; H01L 21/285; H01L 23/528; H01L 23/532

(52) U.S. Cl. CPC H01L 27/11582; H01L 27/11556; H01L 23/528; H01L 23/53266; H01L 21/28556; H01L 21/28568; H01L 21/76877; H01L 21/7685; H01L 21/2855

(57) ABSTRACT

The memory string includes a plurality of control gate electrodes, a semiconductor layer, and an electric charge accumulating layer. The plurality of control gate electrodes are laminated on a substrate. The semiconductor layer has a longitudinal direction in a direction perpendicular to the substrate. The semiconductor layer opposes the plurality of control gate electrodes. The electric charge accumulating layer is disposed between the control gate electrode and the semiconductor layer. The contact includes a contact layer. The contact layer has a long plate shape whose length in a first direction is longer than a length in a second direction. A lower surface of the contact layer is coupled to the substrate. The contact layer includes a first metal layer and a second metal layer. The first metal layer contains tungsten. The second metal layer is disposed over the first metal layer. The second metal layer contains titanium nitride.

### CROSS REFERENCE TO RELATED APPLICATIONS

This application is based on and claims the benefit of priority from prior US prior provisional Patent Application No. 62/153,891, filed on Apr. 28, 2015, the entire contents of which are incorporated herein by reference.

### FIELD

Embodiments described herein relate generally to a semiconductor memory device.

### BACKGROUND

### Description of the Related Art

There has been known a flash memory that accumulates electric charges on an electric charge accumulating layer to store data. Such flash memory is coupled by various methods such as a NAND type and a NOR type, thus constituting a semiconductor memory device. Recently, such non-volatile semiconductor memory devices have been provided with larger capacity and highly integrated. To enhance a degree of integration of the memory, a semiconductor memory device whose memory cells are three-dimensionally disposed (three-dimensional semiconductor memory device) has been proposed.

### BRIEF DESCRIPTION OF THE DRAWINGS

FIG. 1 is a block diagram of a non-volatile semiconductor memory device according to an embodiment;

FIG. 2 is a circuit diagram illustrating a part of a configuration of the non-volatile semiconductor memory device;

FIG. 3 is a perspective view illustrating a part of the configuration of the non-volatile semiconductor memory device;

FIG. 4 is a cross-sectional view illustrating a part of the configuration of the non-volatile semiconductor memory device;

FIG. 5 is a perspective view illustrating a part of the configuration of the non-volatile semiconductor memory device;

FIG. 6 is a cross-sectional view illustrating a part of the configuration of the non-volatile semiconductor memory device;

FIG. 7 to FIG. 18 are cross-sectional views illustrating a part of the configuration of the non-volatile semiconductor memory device, and

FIG. 19 is a graph describing an effect of a non-volatile semiconductor memory device of the embodiment.

### DETAILED DESCRIPTION

According to one embodiment, a semiconductor memory device includes a memory string and a contact. The memory string includes a plurality of memory cells coupled in series. The contact is electrically coupled to one end of the memory string.

The memory string includes a plurality of control gate electrodes, a semiconductor layer, and an electric charge accumulating layer. The plurality of control gate electrodes are laminated on a substrate. One end of the semiconductor layer is coupled to the substrate. The semiconductor layer has a longitudinal direction in a direction perpendicular to the substrate. The semiconductor layer opposes the plurality of control gate electrodes. The electric charge accumulating layer is disposed between the control gate electrode and the semiconductor layer. The contact includes a contact layer. The contact layer has a long plate shape whose length in a first direction is longer than a length in a second direction. The first direction is parallel to the substrate. The second direction intersects with the first direction. A lower surface of the contact layer is coupled to the substrate. The contact layer includes a first metal layer and a second metal layer. The first metal layer contains tungsten. The second metal layer is disposed over the first metal layer. The second metal layer contains titanium nitride.

The following describes non-volatile semiconductor memory devices according to embodiments in detail with reference to the accompanying drawings. Here, these embodiments are only examples, and are not described for the purpose of limiting the present invention. The respective drawings of the non-volatile semiconductor memory devices used in the following embodiments are schematically illustrated. The thickness, the width, the ratio, and a similar parameter of the layer are different from actual parameters.

The following embodiments relate to a non-volatile semiconductor memory device in a structure where a plurality of metal-oxide-nitride-oxide-semiconductor (MONOS) type memory cells (transistors) is disposed in a height direction. The MONOS type memory cell includes: a semiconductor layer disposed in a columnar shape perpendicular to a substrate as a channel, and a gate electrode layer disposed on the side surface of the semiconductor layer via an electric charge accumulating layer. However, this is not also intended to limit the present invention. The present invention is applicable to another type of electric charge accumulating layer, for example, a semiconductor-oxide-nitride-oxide-semiconductor type (SONOS) memory cell or a floating-gate type memory cell.

### First Embodiment

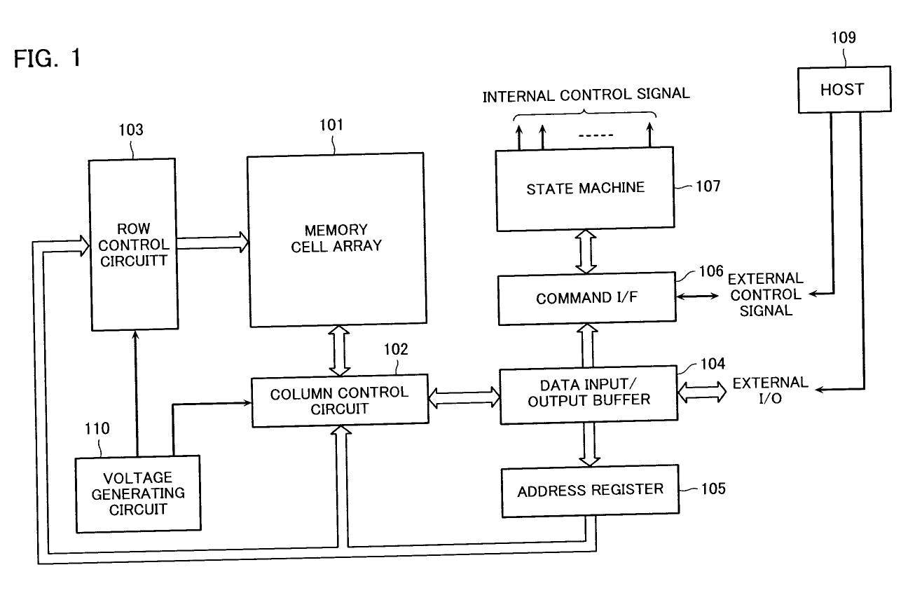

FIG. 1 is a block diagram of a non-volatile semiconductor memory device according to the embodiment. This non-volatile semiconductor memory device includes a memory cell array 101. The memory cell array 101 includes a plurality of memory cells MC, as well as bit lines BL and word lines WL coupled to these memory cells MC. Around this memory cell array 101, a column control circuit 102 and a row control circuit 103 are disposed. The column control circuit 102 controls the bit lines BL to erase data in the memory cells, write data to the memory cells, and read data from the memory cells. The row control circuit 103 selects the word line WL to apply a voltage to erase data in the memory cells, write data to the memory cells, and read data from the memory cells.

A data input/output buffer 104 is coupled to an external host 109 via an I/O line. The data input/output buffer 104 receives writing data, receives a erasure instruction, outputs reading data, and receives address data and command data. The data input/output buffer 104 transmits the received writing data to the column control circuit 102. The data input/output buffer 104 receives the data read from the column control circuit 102 and outputs the data to the outside. The address data supplied from the outside to the data input/output buffer 104 is transmitted to the column control circuit 102 and the row control circuit 103 via an address register 105.

The command data supplied from the host 109 to the data input/output buffer 104 is transmitted to a command interface 106.

The command interface 106 receives an external control signal from the host 109. The command interface 106 determines whether the data input to the data input/output buffer 104 is the writing data, the command data, or the address data. If the input data is the command data, the command interface 106 transfers the data as a receiving command signal to a state machine 107.

The state machine 107 manages the entire non-volatile memory. The state machine 107 accepts the command data from the host 109 via the command interface 106 to manage, for example, reading, writing, erasing, and inputting/outputting the data.

The external host 109 also can receive status information managed by the state machine 107 and determine the operation result. This status information is also used to control the writing and the erasure.

The state machine 107 controls a voltage generating circuit 110. This control allows the voltage generating circuit 110 to output pulses at any given voltage and at any given timing.

The formed pulses can be transferred to any given wiring selected by the column control circuit 102 and the row control circuit 103. These column control circuit 102, row control circuit 103, state machine 107, voltage generating circuit 110, or a similar component configure the control circuit in the embodiment.

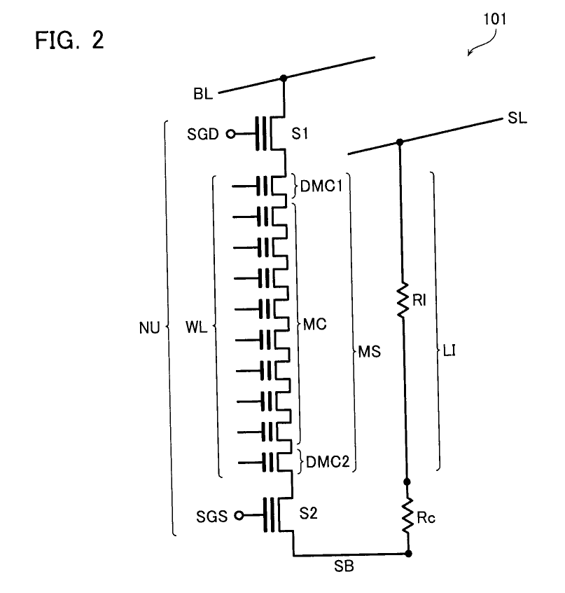

The following describes the circuit configuration of the memory cell array 101 with reference to FIG. 2. FIG. 2 is a circuit diagram illustrating a part of the configuration of the memory cell array 101.

As illustrated in FIG. 2, the memory cell array 101 according to the embodiment includes the plurality of memory cells MC coupled in series and dummy cells DMC1 and DMC2. The dummy cells DMC1 and DMC2 are each coupled to both ends of these memory cells MC. These plurality of memory cells MC and gate electrodes of the dummy cells DMC1 and DMC2 are each coupled to the word lines WL. These plurality of memory cells MC and dummy cells DMC1 and DMC2 configure a memory string MS.

As illustrated in FIG. 2, to both ends of the memory string MS, selection gate transistors S1 and S2 are each coupled. The selection gate transistors S1 and S2 are coupled to selection gate lines SGD and SGS, respectively. These memory string MS and selection gate transistors S1 and S2 configure a NAND cell unit NU.

One end of the NAND cell unit NU is coupled to the bit line BL. The other end of the NAND cell unit NU is coupled to a source line SL via a substrate SB and a source contact LI. At a surface where the substrate SB is in contact with the source contact LI, a contact resistance Rc occurs. In the wiring of the source contact LI, a wiring resistance R1 occurs.

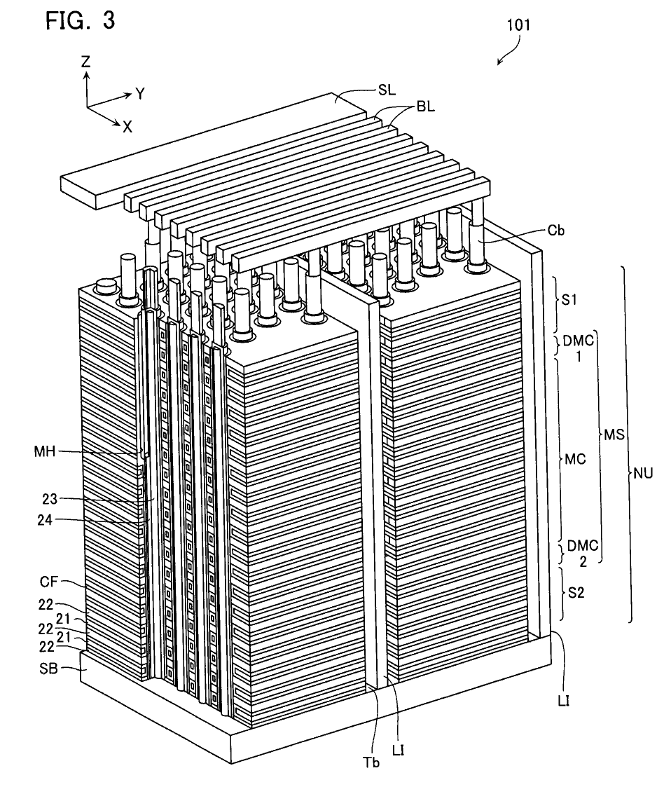

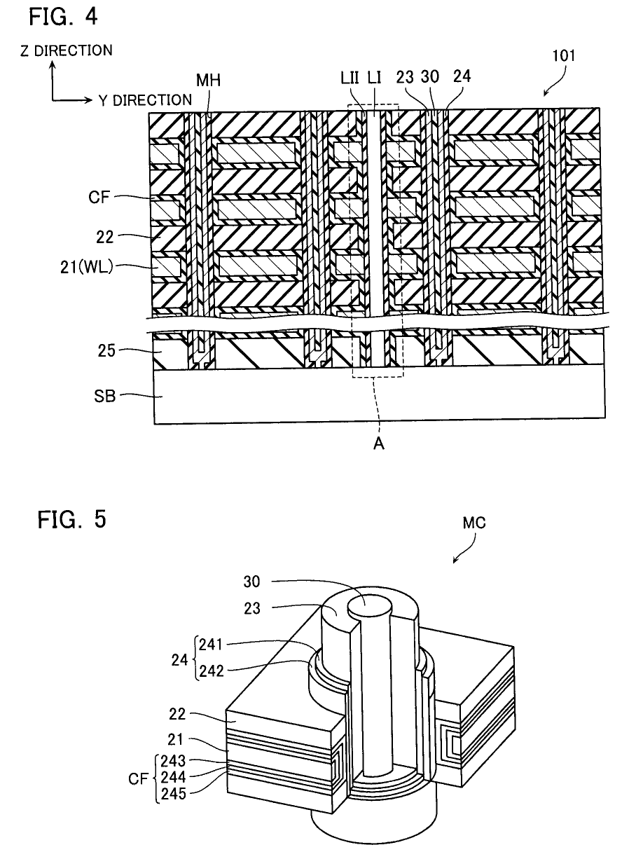

The following describes the configuration of the memory cell array 101 with reference to FIG. 3 to FIG. 5. FIG. 3 is a perspective view illustrating apart of the configuration of the memory cell array 101. FIG. 4 is a cross-sectional view of the memory cell array 101. FIG. 5 is a perspective view illustrating the configuration of the memory cell MC.

As illustrated in FIG. 3, the memory cell array 101 has a structure of laminating interlayer insulating layers 22 and conductive layers 21 in alternation on the semiconductor substrate SB. As illustrated in FIG. 4, at the peripheral area of the conductive layer 21, a laminated film CF including a block insulating layer 243 (FIG. 5) is formed. The conductive layer 21 functions as a control gate (the word line WL) of the memory cell MC, a source side selection gate line SGS, and a drain side selection gate line SGD. The interlayer insulating layers 22 are disposed above and below these conductive layers 21 to electrically insulate the conductive layers 21 mutually. The conductive layer 21 is made of, for example, metal such as tungsten (W) and a material for the conductive layer such as polysilicon to which impurities are added. The interlayer insulating layer 22 is made of an insulating material such as silicon oxide (SiO₂).

As illustrated in FIG. 3, memory holes MH are formed at the interlayer insulating layers 22 and the conductive layers 21 so as to pass through the laminated body of the interlayer insulating layers 22 and the conductive layers 21. The memory holes MH are collocated at, for example, a predetermined pitch in the XY plane. Semiconductor layers 23 are formed in the memory hole MH. The semiconductor layer 23 has the longitudinal direction in the laminating direction (Z direction). The semiconductor layer 23 is formed from the inside of the memory hole MH so as to reach the semiconductor substrate SB. The semiconductor layer 23 opposes the laminated body of the interlayer insulating layers 22 and the conductive layers 21. The semiconductor layer 23 is made of polysilicon or a similar material. The semiconductor layer 23 is covered with a memory layer 24. The memory layer 24 may be configured of a laminated structure of electric charge accumulating layers such as a silicon nitride layer and an oxide layer such as a silicon oxide layer. Depending on the accumulation amount of the electric charge to this electric charge accumulating layer, the threshold voltage of the memory cell MC changes. The memory cell MC holds data corresponding to this threshold voltage.

These semiconductor layers 23 are coupled, on their upper ends, to the bit lines BL via contacts Cb. The bit lines BL having the longitudinal direction in the Y direction are collocated at a predetermined pitch along the X direction.

The lower end of the semiconductor layer 23 is coupled to the semiconductor substrate SB. As described above, the lower end of the semiconductor layer 23 is coupled to the source line SL via this semiconductor substrate SB and the source contact LI, which is described later. The source lines SL are collocated while having their longitudinal directions in the Y direction, similar to the bit lines BL.

Here, the laminated body of the interlayer insulating layers 22 and the conductive layers 21 in the memory cell array 101 is separated by blocks as the smallest unit of data erasure. At the boundary of the separation, a trench Tb is formed. In this trench Tb, an interlayer insulating layer LII (FIG. 4) is embedded. Further, the source contact LI described above is formed passing through the interlayer insulating layer. This source contact LI has a plate shape extending in the X direction. The source contact LI has a lower surface coupled to the semiconductor substrate SB while having an upper end coupled to the source line SL.

As illustrated in FIG. 5, a core insulating layer 30, the semiconductor layer 23, and the memory layer 24 are formed at the memory hole MH in the order from the center. The memory layer 24, for example, includes a tunnel insulating layer 241 and an electric charge accumulating layer 242. The memory layer 24 is in contact with the laminated film CF that covers the conductive layer 21. The laminated film CF includes the block insulating film 243, a block high-dielectric film 244, and a barrier metal 245. The tunnel insulating layer 241 and the block insulating layer 243 are, for example, made of silicon oxide (SiO₂). The electric charge accumulating layer 242 is, for example, made of silicon nitride (SiN). The block high-dielectric film 244 is, for example, made of metal oxide such as alumina (Al₂O₃) and hafnium oxide (HfOₓ). The barrier metal 245 is, for example, made of a metal nitride such as TiN, WN, or TaN.

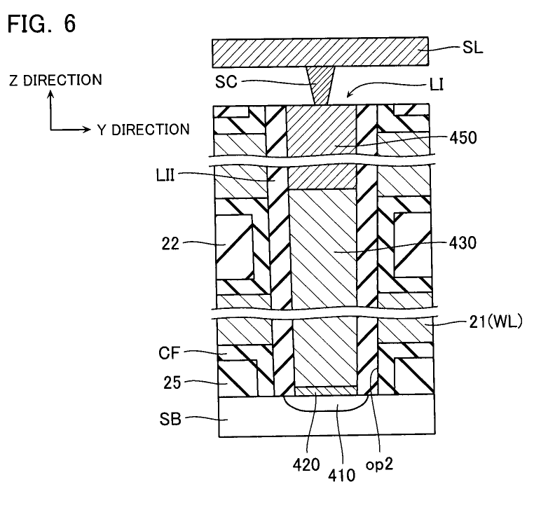

Next, the following describes the configuration of the source contact LI with reference to FIG. 6. FIG. 6 is an enlarged view of the part indicated by A in FIG. 4.

As illustrated in FIG. 6, the source contact LI according to the embodiment includes a silicide layer 410 formed on the substrate SB and a barrier layer 420 formed on the top surface of this silicide layer 410. The silicide layer 410 is, for example, made of titanium silicide (TiSiₓ). The barrier layer 420 is, for example, made of titanium nitride (TiN).

As illustrated in FIG. 6, the source contact LI according to the embodiment includes a first metal layer 430 and a second metal layer 450. The first metal layer 430 is formed on the top surface of the barrier layer 420, and the second metal layer 450 is formed on the top surface of this first metal layer 430. The first metal layer 430 is mainly made of tungsten (W). On the other hand, the second metal layer 450 is mainly made of titanium nitride (TiN). The titanium nitride for the second metal layer 450 is, as described later, preferably deposited by physical vapor deposition method (PVD method).

When depositing the tungsten for the first metal layer 430 by CVD method while depositing the titanium nitride for the second metal layer 450 by the PVD method, an impurity concentration of the former is larger than an impurity concentration of the latter. To deposit the tungsten by the CVD method, tungsten hexafluoride (WF6) is used as a raw material gas, for example. However, an impurity concentration of a material such as fluorine at the tungsten film in this case is several at %. In contrast to this, to deposit the titanium nitride by the PVD method, the impurity concentration is less than 0.1 at %.

The top surface of the second metal layer 450 is coupled to the source line SL via a contact SC. An isolation insulating film LL1 is formed at the sidewalls of the first metal layer 430 and the second metal layer 450. This isolation insulating film LL1 is formed at a sidewall of an opening op2 to electrically insulate the first metal layer 430 and the second metal layer 450 from, for example, other conductive layers.

As illustrated in FIG. 3, the source contact LI has the plate shape extending in the X direction. The first metal layer 430 and the second metal layer 450 also have the similar plate shape.

Here, in the embodiment, electrons may move the inside of the source contact LI in the X direction. Therefore, the wiring resistance R1 inside the source contact LI in the X direction is preferably low (see FIG. 2). To reduce the wiring resistance R1, constituting the source contact LI by only a metallic material such as the tungsten is preferable.

However, if the source contact LI is made of only the tungsten, the substrate warps. Here, since the coefficient of thermal expansion differs between the material such as silicon used for the substrate and the tungsten, tensile stress occurs to the substrate after film formation of the tungsten. In particular, in the case where the source contact LI is formed into the plate shape spreading on the ZX plane, the tensile stress at the ZX plane is likely to be large. Further, since the source contact LI is coupled to the substrate at the lower surface, a contacted area with the substrate is comparatively wide. Therefore, the tensile stress as described above occurs over the wide area, thus warping the substrate as described above.

Accordingly, as illustrated in FIG. 6, the source contact LI according to the embodiment includes the second metal layer 450 made of the titanium nitride in addition to the first metal layer 430 made of tungsten. The volume ratio of the first metal layer 430 to the second metal layer 450 is, as described later, preferably set to around 9:1 to 7:3. The titanium nitride generates compressive stress at the ZX plane unlike the tungsten. In view of this, the source contact LI with the structure of laminating the first metal layer 430, which is made of tungsten, and the second metal layer 450, which is made of titanium nitride, offsets the tensile stress from the first metal layer 430 by the compressive stress from the second metal layer. This totally reduces the tensile stress, ensuring reducing the warping of the substrate.

### [Manufacturing Method]

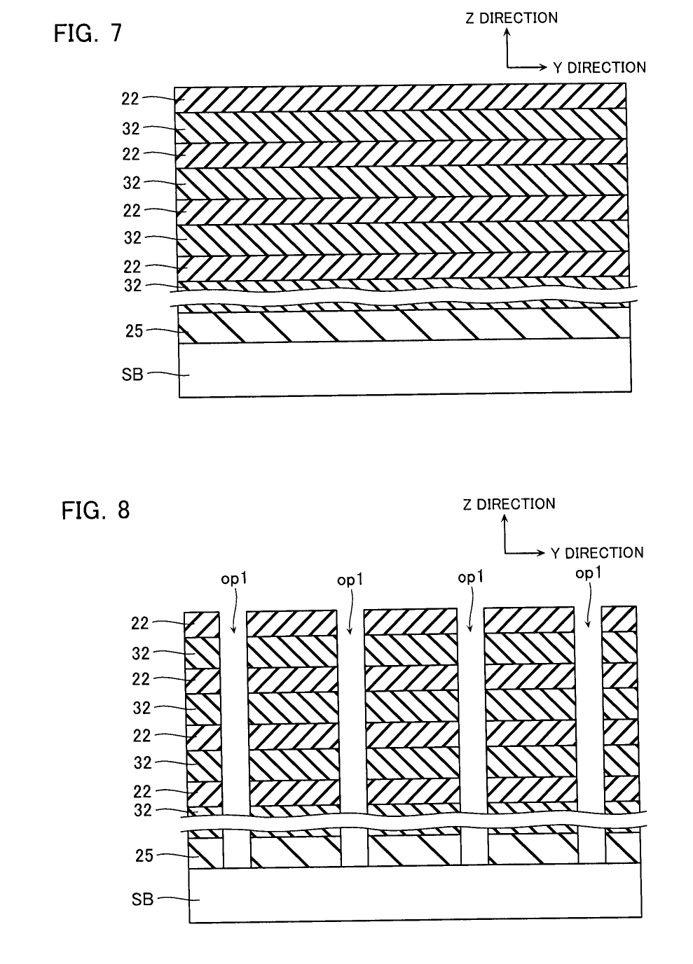

The following describes a method of manufacturing the non-volatile semiconductor according to this embodiment with reference to FIG. 7 to FIG. 18. FIG. 7 to FIG. 18 are cross-sectional views for describing the manufacturing method according to the embodiment.

As illustrated in FIG. 7, an insulating layer 25 is laminated on the semiconductor substrate SB. A plurality of sacrificial layers 32 and the interlayer insulating layers 22 are laminated in alternation on the insulating layer 25. The insulating layer 25 and the interlayer insulating layer 22 are, for example, made of silicon oxide (SiO₂). The sacrificial layer 32 is made of, for example, silicon nitride (SiN).

Next, as illustrated in FIG. 8, openings op1 passing through the insulating layer 25, the sacrificial layers 32, and the interlayer insulating layers 22 are formed. The openings op1 become the memory holes MH.

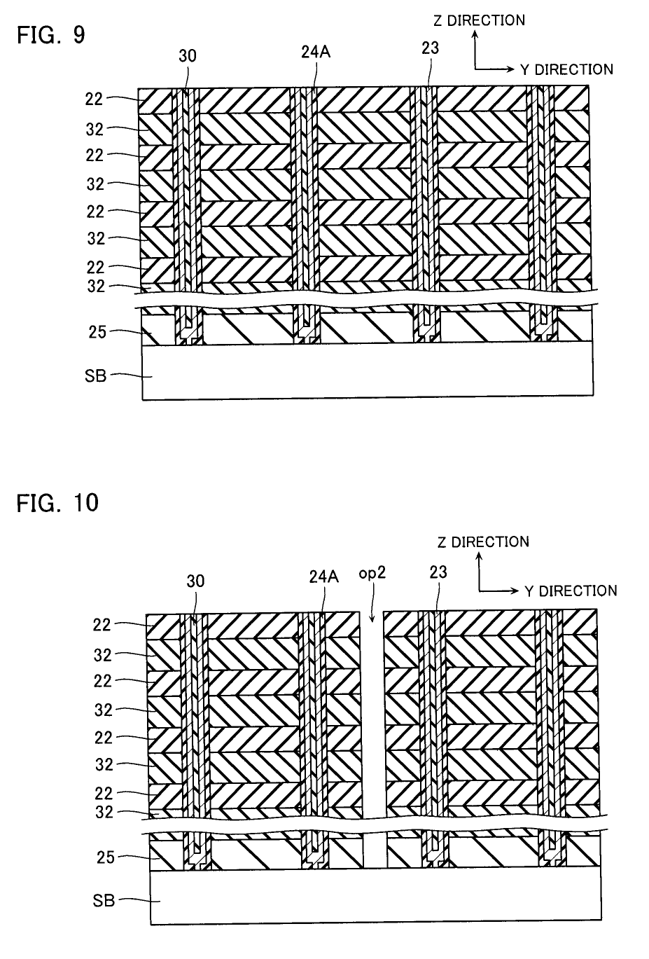

Then, as illustrated in FIG. 9, a memory layer formation layer 24A, which will be the memory layer 24, the semiconductor layer 23, and the core insulating layer 30 are formed in the openings op1. The semiconductor layer 23 is made of, for example, polysilicon. The memory layer 24 is, for example, configured of the laminated film of silicon nitride (SiN) and silicon oxide (SiO₂). The core insulating layer 30 is, for example, made of silicon oxide (SiO₂).

As illustrated in FIG. 10, the opening op2 is formed. The opening op2 separates the insulating layer 25, the sacrificial layers 32, and the interlayer insulating layers 22. The opening op2 will be the above-described trench Tb.

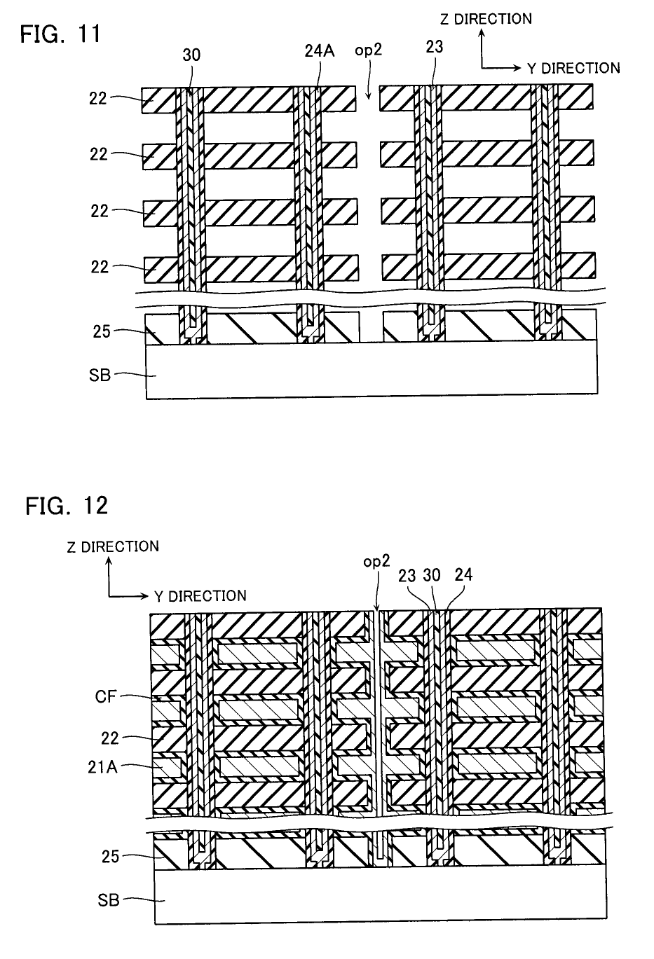

As illustrated in FIG. 11, the sacrificial layers 32 are removed via the opening op2. The sacrificial layers 32 are removed by, for example, wet etching using a phosphoric acid solution.

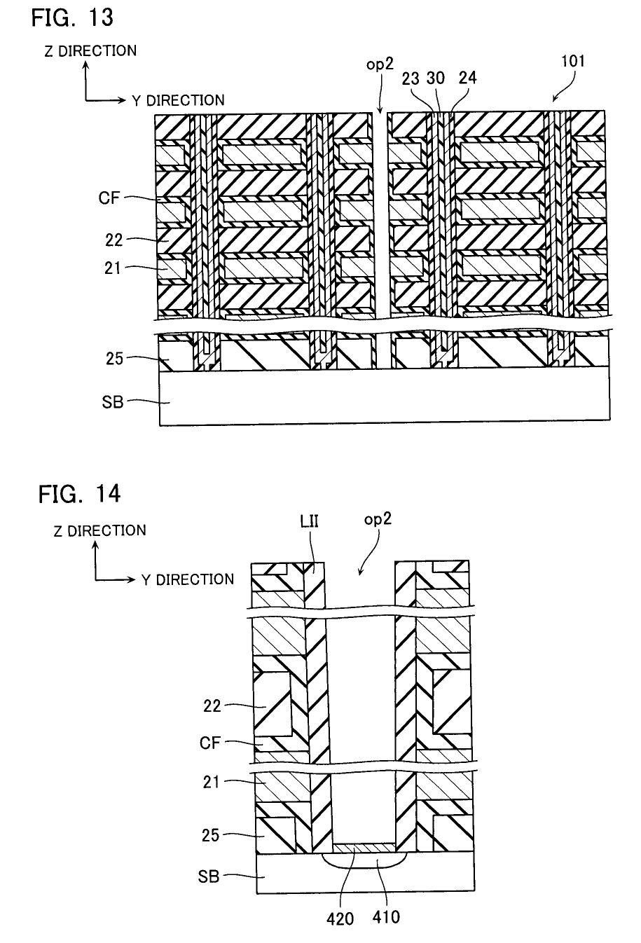

As illustrated in FIG. 12, the laminated films CF and conductive layers 21A, which will be the conductive layers (the word lines WL), are formed at voids where the sacrificial layers 32 was disposed via the opening op2. The laminated films CF and the conductive layers 21A are formed by, for example, chemical vapor deposition (CVD) method. As illustrated in FIG. 13, the conductive layers 21A are etch-backed by the wet etching or a similar method. This removes the conductive layers 21A disposed at the side surfaces of the interlayer insulating layers 22. Accordingly, the conductive layers 21A become the conductive layers 21 insulated and separated in the Z direction by the interlayer insulating layers 22.

Next, as illustrated in FIG. 14, the interlayer insulating layers LII are formed. The interlayer insulating layers LII are formed by, for example, forming films made of SiO₂ at a predetermined film thickness in the opening op2 by the CVD method or a similar method. In the formed SiO₂ film, apart covering the top surface of the substrate SB is removed by anisotropic etching or a similar method. Afterwards, titanium film is deposited on the bottom portion of the opening op2 by the PVD method or a similar method, and then a thermal process is performed on the titanium film. Thus, the silicide layer 410 is formed. Further, the barrier layer 420 made of, for example, titanium nitride is deposited on the top surface of this silicide layer 410.

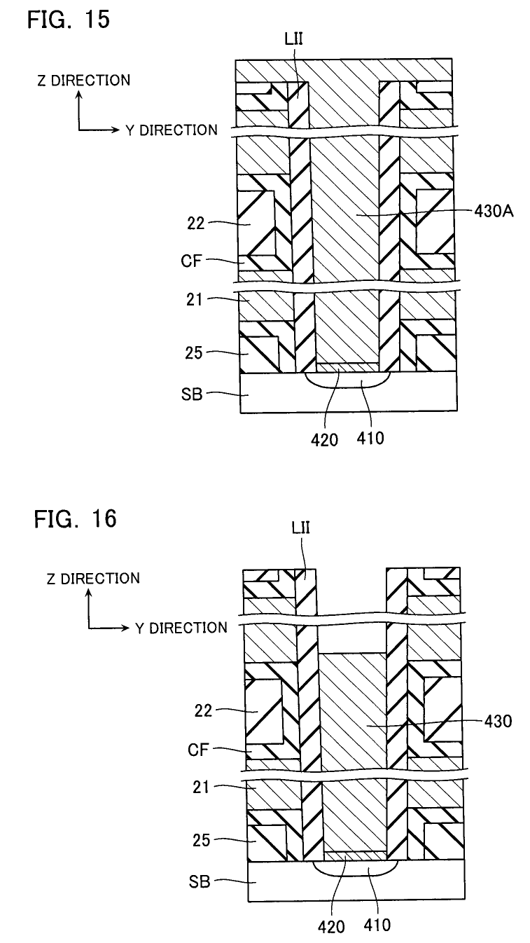

Subsequently, as illustrated in FIG. 15, a first metal layer 430A containing tungsten or a similar material is formed inside the opening op2 by the CVD method. The first metal layer 430A deposited outside the opening op2 is removed by, for example, a CMP method. As one example, tungsten is deposited by the CVD method using tungsten hexafluoride (WF6) as the raw material gas. In this case, the formed first metal layer 430A is a film containing around several at of fluorine as the impurities.

Next, as illustrated in FIG. 16, the first metal layer 430A is etch-backed by, for example, reactive ion etching (RIE) using fluorine gas, thus forming the first metal layer 430. The amount of etchback at this time is preferably adjusted such that a deposition ratio of the first metal layer 430 remaining at the inside of the opening op2 to the second metal layer 450 formed later is within the range of 9:1 to 7:3. More preferably, an aspect ratio of a cavity generated in the opening op2 by the etchback is designed to be less than 8.

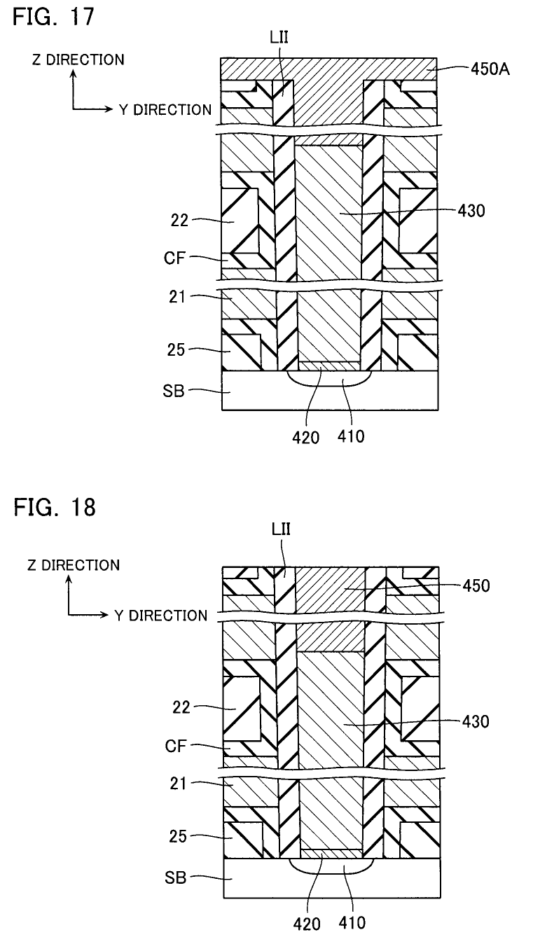

As illustrated in FIG. 17, a second metal film 450A containing titanium nitride or a similar material is deposited on the cavity inside the opening op2, which is generated by this etchback, by the physical vapor deposition method (the PVD method). The PVD method is inferior to the CVD method in embedding characteristics. As described above, the aspect ratio of the cavity of the opening op2 formed at the process in FIG. 16 (a ratio of a length of the cavity in a direction perpendicular to the substrate with respect to a width thereof in a direction parallel to the substrate) may be set to a small value of, for example, around less than 8. In view of this, the PVD method also can fully embed this cavity with a titanium nitride film (the second metal film 450A). The titanium nitride thus embedded by the PVD method generates the compressive stress. Therefore, as described later, this reduces combined stress in the source contact LI, ensuring restraining the warping of the substrate. As illustrated in FIG. 18, the second metal film 450A deposited on the outside of the opening op2 is removed using the CMP or a similar method. Afterwards, the contact (not illustrated), the bit line BL, the source line SL, or a similar member is formed, thus manufacturing the semiconductor memory device according to the embodiment.

As described above, the source contact LI of the embodiment has the two-layer structure of the first metal layer 430, which is mainly made of tungsten, and the second metal layer 450, which is mainly made of titanium nitride. This structure can prevent the substrate from warping.

The source contact LI is configured so as to pass through the plurality of conductive layers 21 and interlayer insulating layers 22 and reach the substrate SB. The source contact LI is formed having a height, for example, around 5 μm in the Z direction. Further, the source contact LI is formed to have the plate shape whose length in the X direction is sufficiently longer than the width in the Y direction. When forming the entire source contact LI with such shape with the tungsten as the material, since the tungsten has the tensile stress, the substrate is possibly warped.

However, the source contact LI of this embodiment forms the first metal layer 430 whose main constituent is the tungsten downward of the source contact LI and the second metal layer 450 whose main constituent is the titanium nitride above the first metal layer 430. The titanium nitride, in particular, the titanium nitride deposited by the PVD method provides the compressive stress unlike the tungsten. Accordingly, the preferable combination of the first metal layer 430 whose main constituent is the tungsten and the second metal layer 450 whose main constituent is the titanium nitride ensures offsetting the tensile stress and the compressive stress. This consequently allows preventing the substrate from warping. The titanium nitride for the second metal layer 450 is preferably deposited by the PVD method from the aspect of generating large compressive stress. Especially, the execution of the PVD method under conditions of a DC power at 22 kW and an RF bias around 400 to 600 W ensures increasing the compressive stress from the titanium nitride. If the compressive stress generated by the titanium nitride is large, the volume ratio of the first metal layer 430 can be increased by the amount, ensuring decreasing the resistance value of the source contact LI.

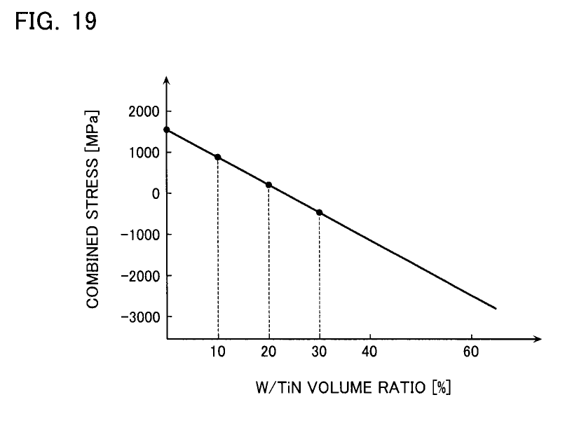

FIG. 19 is a graph illustrating a relationship between the deposition ratio of the tungsten for the first metal layer 430 deposited by the CVD method to the titanium nitride for the second metal layer 450 and the combined stress in the source contact LI. This graph illustrates the case where the titanium nitride for the second metal layer 450 is deposited using the PVD method at the DC power of 22 kW and the RF bias of 400 to 600 W.

As illustrated in FIG. 19, in the case where the source contact LI is all made of tungsten (0%), the combined stress of the source contact LI becomes the tensile stress, and the value of the tensile stress reaches to near 1500 MPa. On the other hand, when the proportion of the second metal layer 450 increases and the volume ratio reaches 10% (9:1), the combined stress (the tensile stress) reduces up to less than 1000 MPa. Further, when the volume ratio of the titanium nitride increases and reaches to 20%, the combined stress becomes almost 0. Further, when the titanium nitride increases and the volume ratio becomes 30% (7:3), the combined stress inversely becomes the compressive stress at −800 MPa. The combined stress falling within the range of −1000 to 1000 MPa can effectively prevent the substrate from warping due to an influence from the source contact LI. Accordingly, the volume ratio of the first metal layer 430 to the second metal layer 450 in the source contact LI is preferably set to around 9:1 to 7:3.

### [Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device, comprising:
a memory string including a plurality of memory cells coupled in series, and
a contact electrically coupled to one end of the memory string, wherein
the memory string includes a plurality of control gate electrodes, a semiconductor layer, and an electric charge accumulating layer, the plurality of control gate electrodes being laminated on a substrate, the semiconductor layer having a longitudinal direction in a direction perpendicular to the substrate, the semiconductor layer opposing the plurality of control gate electrodes, the electric charge accumulating layer being disposed between the control gate electrode and the semiconductor layer,
the contact includes a contact layer having a long plate shape whose length in a first direction is longer than a length in a second direction, the first direction being parallel to the substrate, the second direction intersecting with the first direction, a lower surface of the contact layer being coupled to the substrate, and
the contact layer includes a first metal layer and a second metal layer, the first metal layer containing tungsten, the second metal layer disposed over the first metal layer, the second metal layer containing titanium nitride.

2. The semiconductor memory device according to claim 1, wherein
a volume ratio of the first metal layer to the second metal layer is 9:1 to 7:3.

3. The semiconductor memory device according to claim 1, wherein
an impurity concentration of the first metal layer is larger than an impurity concentration of the second metal layer.

4. The semiconductor memory device according to claim 1, wherein
a proportion of impurity contained in the second metal layer is less than 0.1 at %.

5. The semiconductor memory device according to claim 1, wherein
a ratio of a length of the second metal layer in a direction perpendicular to the substrate with respect to a width of the second metal layer in a direction parallel to the substrate is less than 8.

6. The semiconductor memory device according to claim 2, wherein
an impurity concentration of the first metal layer is larger than an impurity concentration of the second metal layer.

7. The semiconductor memory device according to claim 2, wherein
a proportion of impurity contained in the second metal layer is less than 0.1 at %.

8. The semiconductor memory device according to claim 2, wherein
a ratio of a length of the second metal layer in a direction perpendicular to the substrate with respect to a width of the second metal layer in a direction parallel to the substrate is less than 8.

9. The semiconductor memory device according to claim 1, wherein
one end of the semiconductor layer is coupled to the substrate.

10. The semiconductor memory device according to claim 9, wherein
an impurity concentration of the first metal layer is larger than an impurity concentration of the second metal layer.

11. The semiconductor memory device according to claim 9, wherein
a proportion of impurity contained in the second metal layer is less than 0.1 at %.

12. The semiconductor memory device according to claim 9, wherein
a ratio of a length of the second metal layer in a direction perpendicular to the substrate with respect to a width of the second metal layer in a direction parallel to the substrate is less than 8.

13. A method of manufacturing a semiconductor memory device, comprising:
forming a laminated body where a conductive layer and an interlayer insulating layer are laminated in alternation on a substrate;
forming a first trench that passes through the laminated body and reaches the substrate;
forming a semiconductor layer in the first trench via a memory insulating film to form a memory string, the memory string including the laminated body, the memory insulating film, and the semiconductor layer;
forming a second trench that passes through the laminated body and reaches the substrate;
forming an isolation insulating film at a sidewall of the second trench, subsequently depositing a first metal layer containing tungsten in the second trench by a chemical vapor deposition (CVD); and
depositing a second metal layer containing titanium nitride by a physical vapor deposition method (PVD) over the first metal layer in the second trench to form a contact layer including the first metal layer and the second metal layer.

14. The method of manufacturing the semiconductor memory device according to claim 13, wherein
a volume ratio of the first metal layer to the second metal layer is 9:1 to 7:3.

15. The method of manufacturing the semiconductor memory device according to claim 13, wherein
a ratio of a length of the second metal layer in a direction perpendicular to the substrate with respect to a width of the second metal layer in a direction parallel to the substrate is less than 8.
